(19) United States
(12) Patent Application Publication
(10) Pub. No.: US 2025/0210531 A1
(43) Pub. Date: Jun. 26, 2025

(54) DISPLAY DEVICE

(71) Applicant: Samsung Electronics Co., Ltd., Suwon-si (KR)

(72) Inventor: Kyungkyu KIM, Suwon-si (KR)

(73) Assignee: Samsung Electronics Co., Ltd., Suwon-si (KR)

(21) Appl. No.: 18/968,259

(22) Filed: Dec. 4, 2024

(30) Foreign Application Priority Data
Dec. 22, 2023 (KR) 10-2023-0190336

(51) Int. Cl. H01L 23/538; H01L 23/15; H01L 23/31; H01L 25/16

(52) U.S. Cl. CPC H01L 23/5385; H01L 23/5386; H01L 25/167; H01L 23/15; H01L 23/3107

(57) ABSTRACT

A display device includes a glass substrate having a first surface including a chip region and a display region, a second surface opposite to the first surface, and a third surface extending from the first surface and the second surface and being perpendicular to the first surface, a display panel in the display region on the first surface of the glass substrate, a semiconductor chip in the chip region on the first surface of the glass substrate, a wiring structure surrounding the chip region on the first surface of the glass substrate and the second surface and the third surface of the glass substrate, and a plurality of semiconductor devices below the second surface of the glass substrate.

### CROSS-REFERENCE TO RELATED APPLICATION

This application is based on and claims priority under 35 U.S.C. § 119 to Korean Patent Application No. 10-2023-0190336, filed on Dec. 22, 2023, in the Korean Intellectual Property Office, the disclosure of which is incorporated by reference herein in its entirety.

### BACKGROUND

The inventive concepts relate to display devices, and more particularly, to display devices including a glass substrate.

Electronic apparatuses are becoming more compact and lightweight according to the rapid development of the electronics industry and users' demand. As the electronic apparatuses become smaller and lighter, display devices used therein are also becoming smaller and lighter. In addition, display devices with high reliability along with high performance and large capacity are required. Recently, as the display devices require smaller bezels and thinner panels, there is a greater need to reduce the thicknesses of display modules.

### SUMMARY

The inventive concepts provide display devices that are more compact and have improved reliability.

The objects of the inventive concepts are not limited to the object mentioned above, but other objects not described herein will be clearly understood by those skilled in the art from the following description.

According to an example embodiment of the inventive concepts, a display device may include a glass substrate having a first surface including a chip region and a display region, a second surface opposite to the first surface, and a third surface extending from the first surface and the second surface and being perpendicular to the first surface, a display panel in the display region on the first surface of the glass substrate, a semiconductor chip in the chip region on the first surface of the glass substrate, a wiring structure surrounding the chip region on the first surface of the glass substrate and the second surface and the third surface of the glass substrate, and a plurality of semiconductor devices below the second surface of the glass substrate.

According to an example embodiments of the inventive concepts, a display device may include a glass substrate having a first surface including a chip region and a display region, a second surface opposite to the first surface, and a third surface extending from the first surface and the second surface and being perpendicular to the first surface, a display panel in the display region on the first surface of the glass substrate, a wiring structure extending from the chip region on the first surface of the glass substrate to the second surface of the glass substrate via the third surface of the glass substrate, a semiconductor chip in the chip region on the first surface of the glass substrate and aligned with the display panel in a lateral direction, a plurality of semiconductor devices below the second surface of the glass substrate, and a molding layer being in contact with the second surface of the glass substrate and sealing the plurality of semiconductor devices.

According to an example embodiments of the inventive concepts, a display device may include a glass substrate having a first surface including a chip region and a display region, a second surface opposite to the first surface, and a third surface extending from the first surface and the second surface and being perpendicular to the first surface, a display panel in the display region on the first surface of the glass substrate, a wiring structure including a first redistribution structure in contact with the first surface of the glass substrate, a second redistribution structure in contact with the second surface of the glass substrate, and a third redistribution structure in contact with the third surface of the glass substrate, a semiconductor chip in the chip region on the first surface of the glass substrate and aligned with the display panel in a lateral direction, a plurality of semiconductor devices below the second surface of the glass substrate, and a molding layer being in contact with the second surface of the glass substrate and sealing the plurality of semiconductor devices, wherein the semiconductor chip is on the first redistribution structure and electrically connected to the first redistribution structure, and the second redistribution structure is electrically connected to the plurality of semiconductor devices.

### BRIEF DESCRIPTION OF THE DRAWINGS

Example embodiments will be more clearly understood from the following detailed description taken in conjunction with the accompanying drawings in which:

FIG. 1 is a plan view of a display device according to an example embodiment;

FIG. 2 is a cross-sectional view of the display device taken along line A-A′ of FIG. 1;

FIG. 3 is an enlarged cross-sectional view of region CX1 of FIG. 2;

FIG. 4 is a plan view of a display device according to another example embodiment;

FIG. 5 is a cross-sectional view of the display device taken along line B-B′ of FIG. 4;

FIG. 6 is a side view of the display device of FIG. 4 when viewed from C;

FIG. 7 is a plan view of a display device according to another example embodiment;

FIG. 8 is a cross-sectional view of the display device taken along line D-D′ of FIG. 7;

FIG. 9 is an enlarged cross-sectional view of region CX2 of FIG. 8; and

FIG. 10 is a system diagram including a display device according to an example embodiment.

### DETAILED DESCRIPTION

Hereinafter, some example embodiments are described in detail with reference to the accompanying drawings. The inventive concepts may, however, be embodied in different forms and should not be construed as limited to the example embodiments set forth herein. The following example embodiments are provided to sufficiently convey the scope of the inventive concepts to those skilled in the art rather than to make the inventive concepts thorough and complete.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

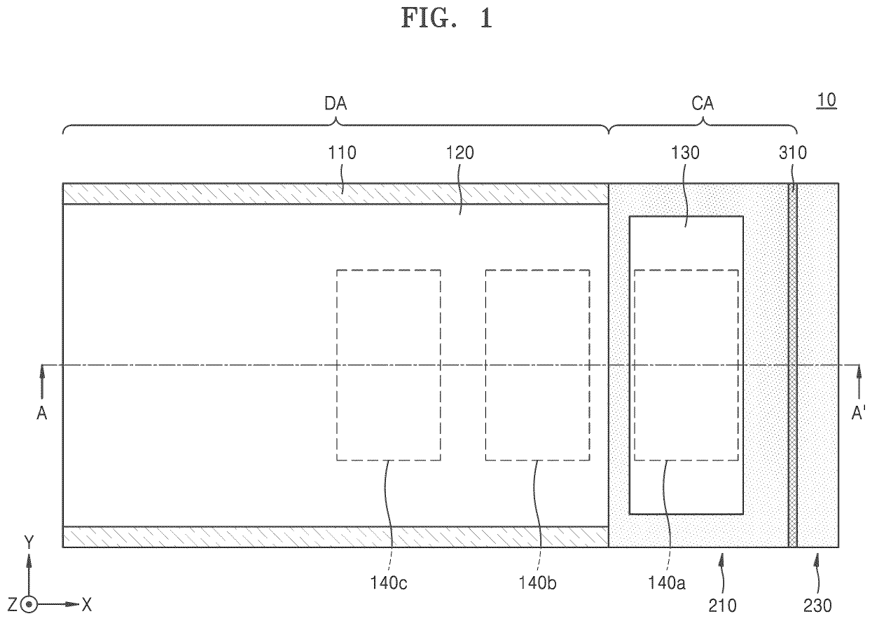

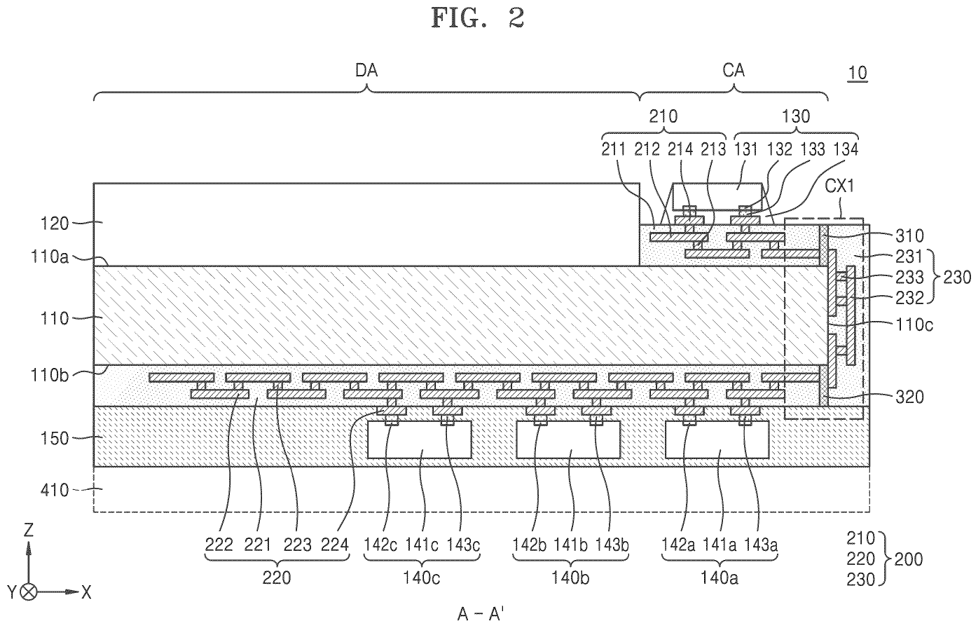

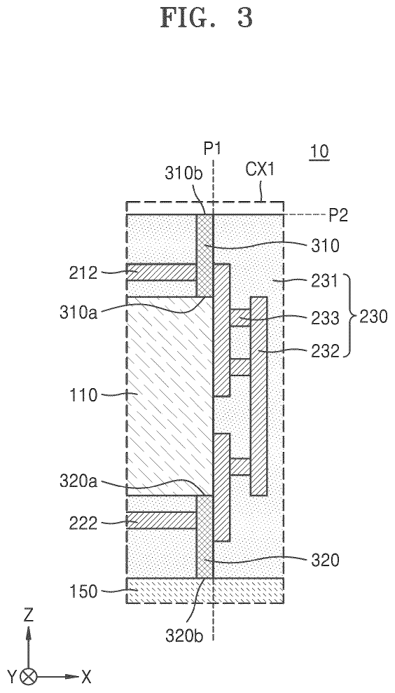

FIG. 1 is a plan view of a display device 10 according to an example embodiment and FIG. 2 is a cross-sectional view of the display device 10 taken along line A-A′ of FIG. 1. FIG. 3 is an enlarged cross-sectional view of region CX1 of FIG. 2.

The display device 10 according to an example embodiment may include a glass substrate 110, a display panel 120, a semiconductor chip 130, a plurality of semiconductor devices 140a, 140b, and 140c, a wiring structure 200, a first conductive layer 310, and a second conductive layer 320. The display device 10 may further include a display module (not shown).

The glass substrate 110 may have a first surface 110a and a second surface 110b opposite to each other. Also, the glass substrate 110 may additionally have a third surface 110c that extends from the first surface 110a and the second surface 110b and is perpendicular to the first surface 110a and the second surface 110b.

As used herein, a direction which is parallel to the first surface 110a and in which the plurality of semiconductor devices 140a, 140b, and 140c are arranged may be referred to as a first horizontal direction (an X direction), and a direction which is parallel to the first surface 110a and perpendicular to the first horizontal direction (the X direction) may be referred to as a second horizontal direction (a Y direction). Also, a direction which is perpendicular to the first horizontal direction (the X direction) and the second horizontal direction (the Y direction) and orthogonal to the first surface 110a may be referred to as a vertical direction (a Z direction).

According to an example embodiment, the glass substrate 110 may be a substrate on which various electronic devices capable of transmitting physical and electrical signals to the display panel 120 are mounted. A height of the glass substrate 110 in the vertical direction (the Z direction) may be in the range of about 0.1 mm to about 3 mm.

According to an example embodiment, the first surface 110a of the glass substrate 110 may be divided into a display region DA and a chip region CA. Also, on the first surface 110a of the glass substrate 110, the display region DA may include a region in which the display panel 120 is provided and the chip region CA may include a region in which the semiconductor chip 130 is provided. The chip region CA is located in the outer circumferential portion on the first surface 110a of the glass substrate 110 in a plan view. In a plan view, the display region DA on the first surface 110a of the glass substrate 110 may be greater than the chip region CA on the first surface 110a of the glass substrate 110.

According to an example embodiment, the display panel 120 may include any type of display panels including a liquid crystal display panel and an organic light emitting diode panel. In some example embodiments in which the display panel 120 includes a liquid crystal display panel, the display panel 120 may include a thin film transistor substrate and a color filter substrate facing each other, and liquid crystal may be injected between the thin film transistor substrate and the color filter substrate. The display panel 120 may display images by adjusting light transmittance of the liquid crystal using a thin film transistor as a switching element. In some example embodiments, a backlight assembly may be further provided to supply light to the display panel 120. In some example embodiments in which the display panel 120 includes an organic light emitting diode panel, the display panel 120 may include a passive matrix-type or active matrix-type organic light emitting diode panel.

According to an example embodiment, the semiconductor chip 130 may include a chip body 131, a connection pad 132, a bump structure 133, and a molding material 134. The semiconductor chip 130 may include a display driver integrated circuit (DDI) chip used to drive the display device 10. The semiconductor chip 130 may operate and control pixels of the display panel 120. The semiconductor chip 130 may include a gate driving integrated circuit for driving a gate line and/or a data driving integrated circuit for driving a data line. In some example embodiments, the semiconductor chip 130 may further include a timing controller, a graphics random access memory (GRAM), and/or a power driver, in addition to the display driver integrated circuit.

In some example embodiments, the semiconductor chip 130 may include a source driving chip that generates an image signal using a data signal transmitted from the timing controller and outputs the image signal to the display panel 120.

Integrated circuit devices for driving the semiconductor chip 130 may be embedded in the chip body 131. The chip body 131 may include a semiconductor substrate having an active surface and an inactive surface opposite to each other. In the example embodiment, the lower surface of the chip body 131 may include an active surface, and the upper surface of the chip body 131 may include an inactive surface. The chip body 131 may include a silicon (Si) wafer that includes crystalline silicon, polycrystalline silicon, or amorphous silicon. The chip body 131 may include semiconductor elements, such as germanium (Ge), or compound semiconductors, such as silicon carbide (SiC), gallium arsenide (GaAs), indium arsenide (InAs), and indium phosphide (InP).

In some example embodiments, the chip body 131 may have a silicon on insulator (SOI) structure. Also, the chip body 131 may include a conductive region, for example, a well doped with impurities or a structure doped with impurities. Also, the chip body 131 may have various device isolation structures, such as a shallow trench isolation (STI) structure.

According to an example embodiment, the semiconductor chip 130 may be mounted, through a flip chip bonding process, on a first redistribution structure 210 located in the chip region CA on the glass substrate 110. In other words, a bump structure 133, such as a solder ball exposed from the active surface of the semiconductor chip 130, is disposed on a first upper pad 214 of the first redistribution structure 210, and the bump structure 133 is physically and electrically coupled to the first upper pad 214 of the first redistribution structure 210. Accordingly, the semiconductor chip 130 may be mounted in the chip region CA on the first surface 110a of the glass substrate 110. A portion of the first upper pad 214 may serve as an input terminal, and another portion of the first upper pad 214 may serve as an output terminal.

The semiconductor chip 130 does not overlap the display panel 120 in the vertical direction (Z direction). That is, the semiconductor chip 130 may be aligned with the display panel 120 in a lateral direction (X direction and/or Y direction) without overlapping each other in the vertical direction (Z direction).

The bump structure 133 and the first upper pad 214 may be in contact and electrically connected to each other. Through the bump structure 133, the semiconductor chip 130 may receive at least one of a control signal, a power signal, or a ground signal for operation of the semiconductor chip 130 from the outside, receive data signals to be stored in the semiconductor chip 130 from the outside, or provide data stored in the semiconductor chip 130 to the outside. For example, the bump structure 133 may include a pillar structure, a ball structure, or a solder resist layer.

A molding material 134 may fill a space between the semiconductor chip 130 and the second redistribution structure 220 in order to protect the bump structure 133 and surroundings thereof from external physical and/or chemical damage. In some example embodiments, the molding material 134 may be formed by a capillary underfill process. The molding material 134 may include, for example, epoxy resin, but example embodiment is not limited thereto.

According to an example embodiment, the wiring structure 200 may cover the first surface 110a, the second surface 110b, and the third surface 110c of the glass substrate 110. The wiring structure 200 may include the first redistribution structure 210, the second redistribution structure 220, and a third redistribution structure 230.

The first redistribution structure 210 may be in contact with the first surface 110a of the glass substrate 110, the second redistribution structure 220 may be in contact with the second surface 110b of the glass substrate 110, and the third redistribution structure 230 may be in contact with the third surface 110c of the glass substrate 110. When viewed from a cross-section perpendicular to the first surface 110a (e.g., the cross-section perpendicular to the first horizontal direction (X direction) and vertical direction (Z direction)), the wiring structure 200 is bent at the corner of the glass substrate 110 and extends in a direction perpendicular to the first surface 110a of the glass substrate 110. That is, the wiring structure 200 extends along the first surface 110a of the glass substrate 110, then is bent at the corner of the glass substrate 110, and extends along the third surface 110c of the glass substrate 110. Subsequently, the wiring structure 200 is bent again at the corner of the glass substrate 110 and extends along the second surface 110b of the glass substrate 110.

The first redistribution structure 210 may be located in the chip region CA on the first surface 110a of the glass substrate 110 and aligned with the display panel 120 in the first horizontal direction (X direction) on the first surface 110a of the glass substrate 110 in a plan view. The first redistribution structure 210 may include a first insulating layer 211, a first conductive pattern 212, a first conductive via 213, and a first upper pad 214.

The first insulating layer 211 may extend with a constant thickness along the first surface 110a of the glass substrate 110. The first insulating layer 211 may include, for example, an inorganic insulating material, an organic insulating material, or a combination thereof. The inorganic insulating material may include, for example, a silicon oxide, a silicon nitride, or a combination thereof. The organic insulating material may include, for example, polyimide, epoxy resin, or a combination thereof.

The first conductive pattern 212 may be provided in plurality, and the plurality of first conductive patterns 212 may be buried in the first insulating layer 211 and extend in the lateral direction (X direction and/or Y direction). The plurality of first conductive patterns 212 may have different vertical levels. The first conductive via 213 may be located between the plurality of first conductive patterns 212 at different vertical levels and extend in the vertical direction (Z direction). The first conductive via 213 may be in contact with the plurality of first conductive patterns 212 at different vertical levels. The first conductive via 213 may be in contact with the lower surface of the first conductive pattern 212 at a relatively high vertical level and the upper surface of the first conductive pattern 212 at a relatively low vertical level.

For example, each of the first conductive pattern 212 and the first conductive via 213 may include a conductive material that includes copper (Cu), gold (Au), silver (Ag), nickel (Ni), tungsten (W), aluminum (Al), or a combination thereof. In some example embodiment, the first conductive pattern 212 and the first conductive via 213 may further include barrier materials that mitigate or prevent the conductive materials from diffusing out of the first conductive pattern 212 and the first conductive via 213. The barrier material may include, for example, titanium (Ti), tantalum (Ta), titanium nitride (TiN), tantalum nitride (TaN), or a combination thereof.

The first upper pad 214 may be disposed on the upper surface of the first insulating layer 211. Unlike the first conductive pattern 212, the first upper pad 214 may be not buried in the first insulating layer 211 but exposed from the first insulating layer 211. The first upper pad 214 may be attached to the bump structure 133 of the semiconductor chip 130 and serve as an input terminal or an output terminal. The first upper pad 214 may be physically and electrically connected to the first conductive pattern 212 and the first conductive via 213 and thus electrically connected to the second redistribution structure 220 and the third redistribution structure 230, which are electrically connected to the first redistribution structure 210.

For example, the first upper pad 214 may include the conductive material of the first conductive pattern 212 or the first conductive via 213. Therefore, repeated descriptions of the conductive material are omitted.

The second redistribution structure 220 may be disposed on the second surface 110b of the glass substrate 110. The first redistribution structure 210 is located only in the chip region CA, which is a partial region of the first surface 110a of the glass substrate 110. However, in contrast, the second redistribution structure 220 may be disposed over the entire region of the second surface 110b of the glass substrate 110. The second redistribution structure 220 may include a second insulating layer 221, a second conductive pattern 222, a second conductive via 223, and a second upper pad 224.

The second insulating layer 221 may extend with a constant thickness along the second surface 110b of the glass substrate 110. The second insulating layer 221 may include, for example, an inorganic insulating material, an organic insulating material, or a combination thereof. The inorganic insulating material may include, for example, a silicon oxide, a silicon nitride, or a combination thereof. The organic insulating material may include, for example, polyimide, epoxy resin, or a combination thereof.

The second conductive pattern 222 may be provided in plurality, and the plurality of second conductive patterns 222 may be buried in the second insulating layer 221 and extend in the lateral direction (X direction and/or Y direction). The plurality of second conductive patterns 222 may have different vertical levels. The second conductive via 223 may be located between the plurality of second conductive patterns 222 at different vertical levels and extend in the vertical direction (Z direction). The second conductive via 223 may be in contact with the plurality of second conductive patterns 222 at different vertical levels. The second conductive via 223 may be in contact with the lower surface of the second conductive pattern 222 at a relatively high vertical level and the upper surface of the second conductive pattern 222 at a relatively low vertical level.

For example, each of the second conductive pattern 222 and the second conductive via 223 may include a conductive material that includes copper (Cu), gold (Au), silver (Ag), nickel (Ni), tungsten (W), aluminum (Al), or a combination thereof. In some example embodiment, the second conductive pattern 222 and the second conductive via 223 may further include barrier materials that prevent the conductive materials from diffusing out of the second conductive pattern 222 and the second conductive via 223. The barrier material may include, for example, titanium (Ti), tantalum (Ta), titanium nitride (TiN), tantalum nitride (TaN), or a combination thereof.

The second upper pad 224 may be disposed on the lower surface of the second insulating layer 221. Unlike the second conductive pattern 222, the second upper pad 224 may be not buried in the second insulating layer 221 but exposed from the second insulating layer 221. The second upper pad 224 may be bonded to the connection terminals 143a, 143b, and 143c of the plurality of semiconductor devices 140a, 140b, and 140c and serve as an input terminal or output terminal for the plurality of semiconductor devices 140a, 140b, and 140c.

The third redistribution structure 230 may be disposed on the third surface 110c of the glass substrate 110. In a plan view, the first redistribution structure 210 is surrounded by the region of the first surface 110a of the glass substrate 110 and the second redistribution structure 220 is arranged to correspond to the region of the second surface 110b. However, the third redistribution structure 230 may be arranged to protrude from the third surface 110c in a plan view. That is, the area of the upper surface (the area of the surface perpendicular to the first horizontal direction (X direction)) of the third redistribution structure 230 may be greater than the area of the third surface 110c of the glass substrate 110.

The third redistribution structure 230 may include a third insulating layer 231, a third conductive pattern 232, and a third conductive via 233.

The third insulating layer 231 may extend with a constant thickness along the third surface 110c of the glass substrate 110. The third insulating layer 231 may include, for example, an inorganic insulating material, an organic insulating material, or a combination thereof. The inorganic insulating material may include, for example, a silicon oxide, a silicon nitride, or a combination thereof. The organic insulating material may include, for example, polyimide, epoxy resin, or a combination thereof.

The third conductive pattern 232 may be provided in plurality, and the plurality of third conductive patterns 232 may be buried in the third insulating layer 231 and extend in a lateral direction (Z direction of FIG. 3). The plurality of third conductive patterns 232 may have different vertical levels in the X direction. The third conductive via 233 may be located between the plurality of third conductive patterns 232 at different vertical levels and extend in the vertical direction (X direction). The third conductive via 233 may be in contact with the plurality of third conductive patterns 232 at different vertical levels. The third conductive via 233 may be in contact with the lower surface of the third conductive pattern 232 at a relatively high vertical level and the upper surface of the third conductive pattern 232 at a relatively low vertical level. Because the third redistribution structure 230 is attached to the third surface 110c of the glass substrate 110 in a 90-degree rotated state, the vertical direction (X direction) of the third redistribution structure 230 is the same as the first horizontal direction (X direction) of the first redistribution structure 210. Similarly, for the same reason, the lateral direction (Z direction) of the third redistribution structure 230 is the same as the vertical direction (Z direction) of the first redistribution structure 210.

For example, each of the third conductive pattern 232 and the third conductive via 233 may include a conductive material that includes copper (Cu), gold (Au), silver (Ag), nickel (Ni), tungsten (W), aluminum (Al), or a combination thereof. In some example embodiment, the third conductive pattern 232 and the third conductive via 233 may further include barrier materials that prevent the conductive materials from diffusing out of the third conductive pattern 232 and the third conductive via 233. The barrier material may include, for example, titanium (Ti), tantalum (Ta), titanium nitride (TiN), tantalum nitride (TaN), or a combination thereof.

According to an example embodiment, the semiconductor devices 140a, 140b, and 140c (or referred to as the first to third semiconductor devices 140a, 140b, and 140c) may include an electronic device for operating the display panel 120. The first to third semiconductor devices 140a, 140b, and 140c may be disposed below the second surface 110b of the glass substrate 110. The electronic device may include a display driver integrated circuit (IC) or additional IC chips. The additional IC chips may include a power management IC, a processor, a memory, a timing controller, a touch sensor IC, a wireless controller, and/or a communications IC. Furthermore, the first to third semiconductor devices 140a, 140b, and 140c may include a modulator/demodulator (MODEM) or access point (AP). The first to third semiconductor devices 140a, 140b, and 140c are directly mounted on the second surface 110b of the glass substrate 110, rather than being mounted on another board (e.g., a printed circuit board (PCB)) and electrically connected to the display panel 120. Accordingly, a more integrated display device 10 may be obtained.

The first semiconductor device 140a may include a first substrate 141a, a first conductive pad 142a, and a first connection terminal 143a. The electronic devices described above may be arranged within the first substrate 141a. The first substrate 141a may include a semiconductor substrate having an active surface and an inactive surface opposite to each other. For example, the first substrate 141a may include a silicon (Si) wafer that includes crystalline silicon, polycrystalline silicon, or amorphous silicon. In some example embodiments, the first substrate 141a may include semiconductor elements, such as germanium (Ge), or compound semiconductors, such as silicon carbide (SiC), gallium arsenide (GaAs), indium arsenide (InAs), and indium phosphide (InP).

In some example embodiments, the first substrate 141a may have an SOI structure. The first substrate 141a may include a conductive region, for example, a well doped with impurities or a structure doped with impurities. Further, the first substrate 141a may have various device isolation structures, such as an STI structure.

The first conductive pad 142a may be disposed on the active surface of the first substrate 141a, and the first connection terminal 143a may be bonded to the first conductive pad 142a. The first conductive pad 142a may have a pillar structure, a ball structure, or a solder resist layer. The first conductive pad 142a may include a conductive material that includes, for example, copper (Cu), gold (Au), silver (Ag), nickel (Ni), tungsten (W), aluminum (Al), or a combination thereof. The first connection terminal 143a may be bonded to the second upper pad 224 and physically and electrically connected to the second redistribution structure 220. That is, the first semiconductor device 140a may be mounted on the second redistribution structure 220 through a flip chip bonding process.

According to an example embodiment, the second semiconductor device 140b may include a second substrate 141b, a second conductive pad 142b, and a second connection terminal 143b. Also, the third semiconductor device 140c may include a third substrate 141c, a third conductive pad 142c, and a third connection terminal 143c. Also, the second substrate 141b and the third substrate 141c may be substantially the same as the first substrate 141a, and the second conductive pad 142b and the third conductive pad 142c may be substantially the same as the first conductive pad 142a. Also, the second connection terminal 143b and the third connection terminal 143c may be substantially the same as the first connection terminal 143a. Therefore, detailed descriptions of the second substrate 141b, the third substrate 141c, the second conductive pad 142b, the third conductive pad 142c, the second connection terminal 143b, and the third connection terminal 143c are omitted below.

Like the first semiconductor device 140a, the second semiconductor device 140b and the third semiconductor device 140c may be mounted on the second redistribution structure 220 through a flip chip bonding process.

According to an example embodiment, a molding layer 150 may be disposed on the lower surface of the second redistribution structure 220. The molding layer 150 may be configured to seal the plurality of semiconductor devices 140a, 140b, and 140c on the lower surface of the second redistribution structure 220. The molding layer 150 may include, for example, a thermosetting resin, such as epoxy resin, or a thermoplastic resin, such as polyimide. Also, a molding material, such as an epoxy mold compound (EMC), or a photosensitive material, such as a photoimageable encapsulant (PIE), may be used as the molding layer 150. In some example embodiments, the molding layer 150 may include a composite material that includes a matrix and fillers within the matrix. The matrix may include a polymer, and the filler may include silica, titania, or a combination thereof. The molding layer 150 may be in contact with the second redistribution structure 220 and the third redistribution structure 230.

According to an example embodiment, a battery 410 may be disposed below the molding layer 150. The battery 410 may include, for example, a non-rechargeable primary cell, a rechargeable secondary cell, and/or a fuel cell.

According to an example embodiment, the first conductive layer 310 may be located between the first redistribution structure 210 and the third redistribution structure 230 and configured to attach the third redistribution structure 230 to the first redistribution structure 210.

As shown in FIG. 3, the first conductive layer 310 may provide a first side surface 310a and a second side surface 310b opposite to the first side surface 310a. The first side surface 310a of the first conductive layer 310 may be in contact with the glass substrate 110, and the second side surface 310b of the first conductive layer 310 may be exposed to the outside of the first redistribution structure 210 or the third redistribution structure 230. The surface of the first conductive layer 310 in contact with the third redistribution structure 230 may be coplanar with the third surface 110c of the glass substrate 110. Also, the surface of the first conductive layer 310 in contact with the third redistribution structure 230 may have the same horizontal level P1 as the third surface 110c of the glass substrate 110, when viewed from a side (e.g., in the X direction).

The second side surface 310b of the first conductive layer 310 may be coplanar with the upper surface of the first redistribution structure 210, and the second side surface 310b of the first conductive layer 310 and the upper surface of the first redistribution structure 210 may have the same vertical level P2 in the Z direction.

The first conductive layer 310 may be in contact with the first conductive pattern 212 and the third conductive pattern 232 and physically and electrically connected to the first conductive pattern 212 and the third conductive pattern 232. Accordingly, the first redistribution structure 210 and the third redistribution structure 230 may be physically and electrically connected to each other via the first conductive layer 310.

According to an example embodiment, the second conductive layer 320 may be located between the second redistribution structure 220 and the third redistribution structure 230 and configured to attach the third redistribution structure 230 to the second redistribution structure 220.

As shown in FIG. 3, the second conductive layer 320 may provide a third side surface 320a and a fourth side surface 320b opposite to the third side surface 320a. The third side surface 320a of the second conductive layer 320 may be in contact with the glass substrate 110, and the fourth side surface 320b of the second conductive layer 320 may be exposed to the outside of the second redistribution structure 220 or the third redistribution structure 230. The surface of the second conductive layer 320 in contact with the third redistribution structure 230 may be coplanar with the third surface 110c of the glass substrate 110. Further, the surface of the second conductive layer 320 in contact with the third redistribution structure 230 may have the same horizontal level P1 as the third surface 110c of the glass substrate 110 when viewed from a side (e.g., in the X direction). In addition, the fourth side surface 320b of the second conductive layer 320 may be coplanar with the lower surface of the second redistribution structure 220.

The second conductive layer 320 may be in contact with the second conductive pattern 222 and the third conductive pattern 232 and physically and electrically connected to the second conductive pattern 222 and the third conductive patterns 232. Accordingly, the second redistribution structure 220 and the third redistribution structure 230 may be physically and electrically connected to each other via the second conductive layer 320.

According to an example embodiment, when the first conductive layer 310 and the second conductive layer 320 are not present, the third redistribution structure 230 is not fixed on the third surface 110c and may fall due to gravity. However, the third redistribution structure 230 may be bonded to the first redistribution structure 210 and the second redistribution structure 220 by the first conductive layer 310 and the second conductive layer 320, respectively, and may be thus fixed to the third surface 110c of the glass substrate 110.

According to an example embodiment, the width of the first conductive layer 310 in the vertical direction (Z direction) is equal to the width of the first redistribution structure 210 in the vertical direction (Z direction). The first side surface 310a of the first conductive layer 310 is coplanar with the first surface 110a of the glass substrate 110. When the width of the first conductive layer 310 in the vertical direction (Z direction) is not equal to the width of the first redistribution structure 210 in the vertical direction (Z direction), the first conductive layer 310 may have a shape protruding or recessed from the wiring structure 200. Similarly, the width of the second conductive layer 320 in the vertical direction (Z direction) is equal to the width of the second redistribution structure 220 in the vertical direction (Z direction). The third side surface 320a of the second conductive layer 320 is coplanar with the second surface 110b of the glass substrate 110. When the width of the second conductive layer 320 in the vertical direction (Z direction) is not equal to the width of the second redistribution structure 220 in the vertical direction (Z direction), the second conductive layer 320 may have a shape protruding or recessed from the wiring structure 200.

According to an example embodiment, the first conductive layer 310 and the second conductive layer 320 may include a conductive adhesive material. For example, the conductive adhesive material may include layers that include a conductive tape, a metal sheet, an adhesive layer, etc. The conductive adhesive material may include a material for bonding metal to metal.

The display device 10 according to the present example embodiment may include the wiring structure 200 that is attached to the first surface 110a and the second surface 110b of the glass substrate 110 and provides electrical connection therebetween. Therefore, electronic devices, such as the semiconductor chip 130 or the plurality of semiconductor devices 140a, 140b, and 140c, may be mounted on the first surface 110a and the second surface 110b of the glass substrate 110, respectively. Thus, a more compact and integrated display device 10 may be provided. The semiconductor chip 130 or the semiconductor devices 140a, 140b, and 140c are mounted on the first surface 110a and the second surface 110b of the glass substrate 110, respectively, which may replace chip-on-film packages according to the related art. Therefore, a more integrated structure may be obtained.

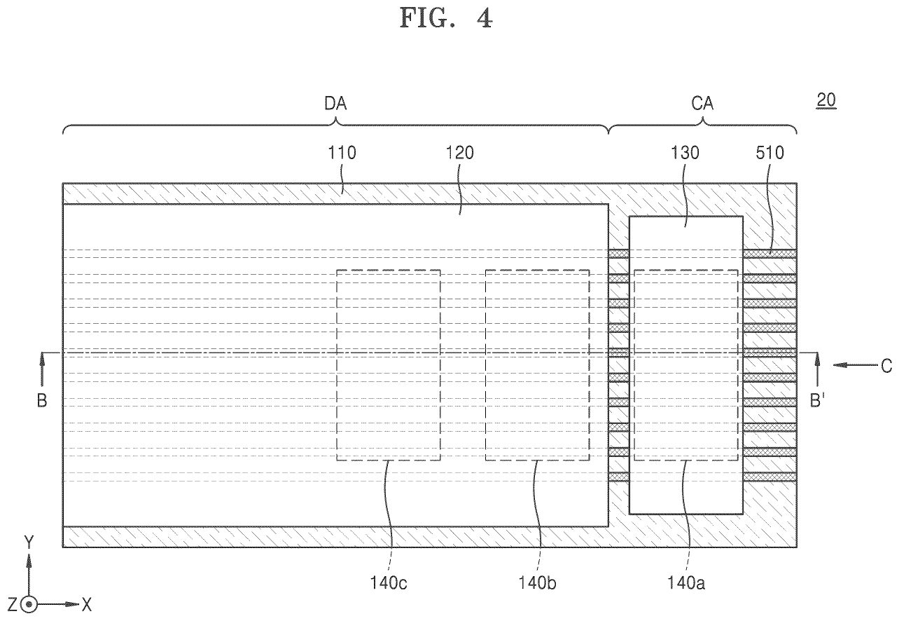

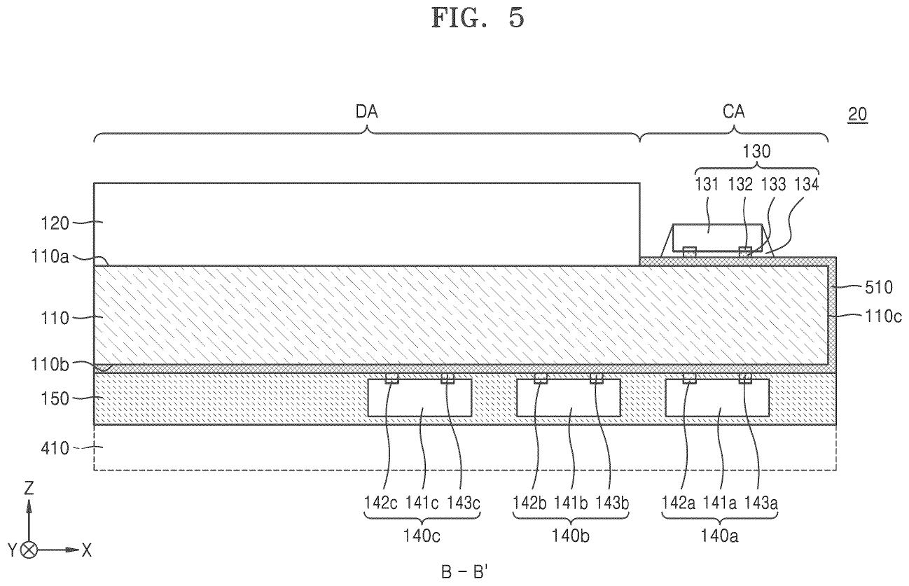

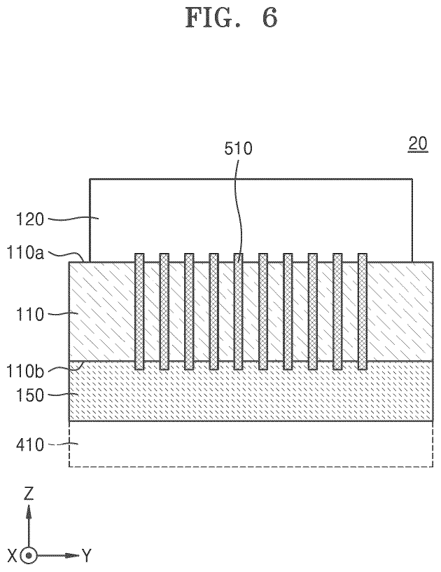

FIG. 4 is a plan view of a display device 20 according to another example embodiment and FIG. 5 is a cross-sectional view of the display device 20 taken along line B-B′ of FIG. 4. Also, FIG. 6 is a side view of the display device 20 of FIG. 4 when viewed from C.

The display device 20 shown in FIGS. 4 to 6 is substantially the same as or similar to the display device 10 shown in FIGS. 1 to 3, except that the wiring structure includes a plurality of conductive lines 510, rather than a plurality of redistribution structures 200. Therefore, descriptions of the components already given above with reference to FIGS. 1 and 3 are omitted.

According to an example embodiment, the wiring structure of the display device 20 may include the plurality of conductive lines 510 that extend from the chip region CA on the first surface 110a of the glass substrate 110 to the second surface 110b of the glass substrate 110 via the third surface 110c of the glass substrate 110. Each of the plurality of conductive lines 510 may include a single conductive line extending from the chip region CA. The plurality of conductive lines 510 may be spaced apart from each other in the second horizontal direction (Y direction). Each of the plurality of conductive lines 510 may include a conductive material that includes, for example, copper (Cu), gold (Au), silver (Ag), nickel (Ni), tungsten (W), aluminum (Al), or a combination thereof.

According to an example embodiment, the plurality of conductive lines 510 may be in contact with the first surface 110a, the second surface 110b, and the third surface 110c of the glass substrate 110. The semiconductor chip 130 may be physically and electrically connected to the plurality of conductive lines 510 on the first surface 110a. The semiconductor chip 130 may be mounted on the plurality of conductive lines 510 using a flip chip method. Also, the bump structure 133 may be bonded to the plurality of conductive lines 510.

The plurality of semiconductor devices 140a, 140b, and 140c may be physically and electrically connected to the plurality of conductive lines 510 on the second surface 110b. The plurality of semiconductor devices 140a, 140b, and 140c may be mounted on the plurality of conductive lines 510 using a flip chip method.

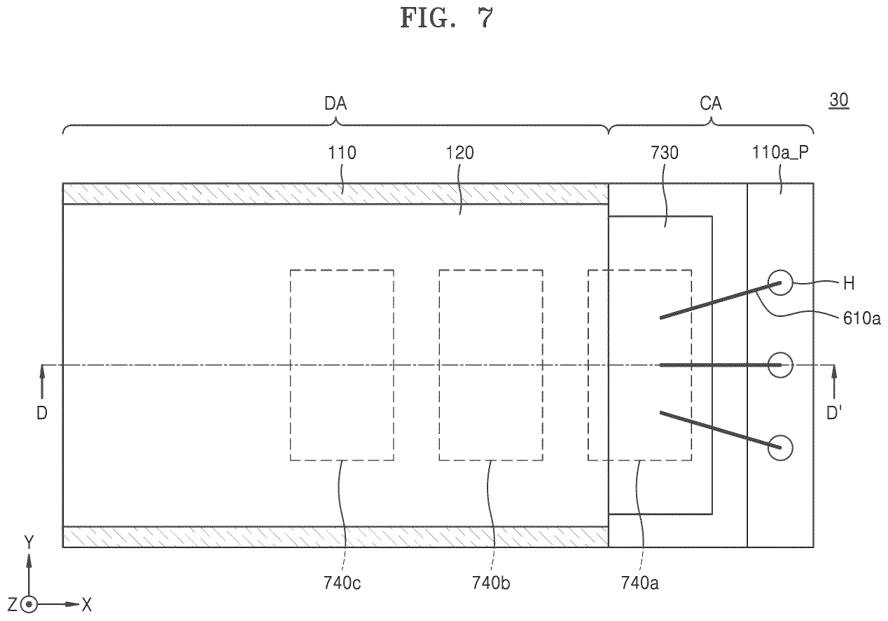

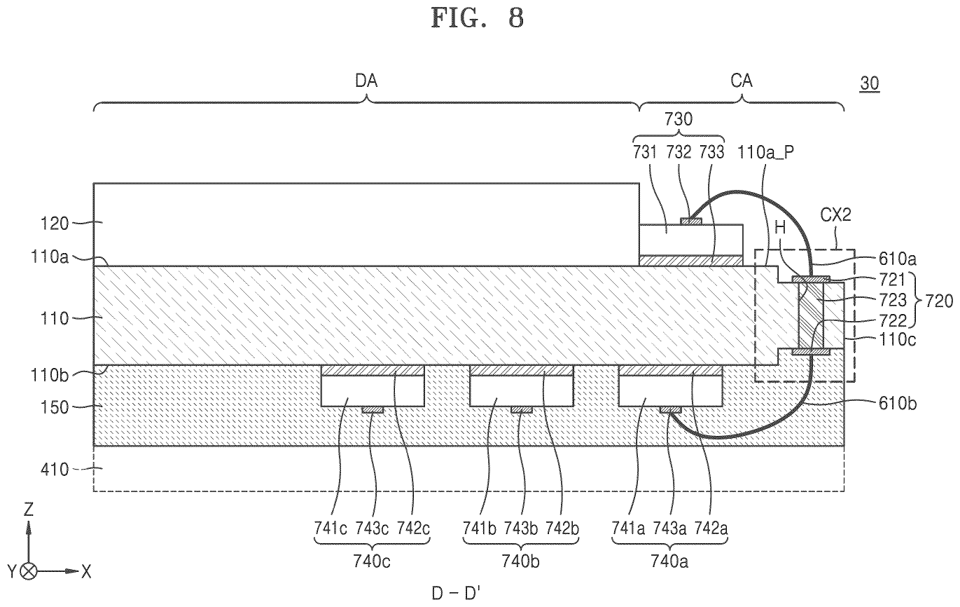

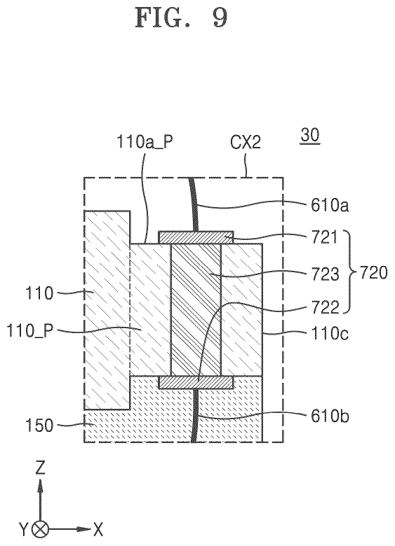

FIG. 7 is a plan view of a display device 30 according to another example embodiment and FIG. 8 is a cross-sectional view of the display device 30 taken along line D-D′ of FIG. 7. Also, FIG. 9 is an enlarged cross-sectional view of region CX2 of FIG. 8.

The display device 30 shown in FIGS. 7 to 9 is substantially the same as or similar to the display device 10 shown in FIGS. 1 to 3, except for the shapes of a semiconductor chip 730 and a plurality of semiconductor devices 740a, 740b, and 740c and the method of connecting the semiconductor chip 730 to the plurality of semiconductor devices 740a, 740b, and 740c. Therefore, descriptions of the components already given above with reference to FIGS. 1 and 3 are omitted, and the description focuses on differences therebetween.

Referring to FIGS. 7 to 9, a semiconductor chip 730 may be disposed on the first surface 110a of the glass substrate 110. The semiconductor chip 730 may include a chip body 731, a chip insulating layer 733, and a chip conductive pad 732. Unlike the chip body 131 shown in FIGS. 1 to 3, the lower surface of the chip body 731 shown in FIGS. 7 to 9 may have an inactive surface, and the upper surface of the chip body 731 may have an active surface. Unlike the semiconductor chip 130 shown in FIGS. 1 to 3, the semiconductor chip 730 shown in FIGS. 7 to 9 may be mounted on the first surface 110a using a wire bonding method. The semiconductor chip 730 may be mounted in the chip region CA on the first surface 110a of the glass substrate 110.

Because integrated circuit devices or electronic devices of the chip body 731 of the display device 30 are the same as integrated circuit devices or electronic devices of the display device 10 (see FIG. 2), repeated descriptions thereof are omitted.

The semiconductor chip 730 may be bonded to the first surface 110a of the glass substrate 110 via the chip insulating layer 733. The semiconductor chip 730 may be bonded, in a face-up state, to the first surface 110a of the glass substrate 110. Further, the upper surface of the semiconductor chip 730 may include an active surface. The chip insulating layer 733 may be attached along the inactive surface of the chip body 731.

The chip conductive pad 732 may be disposed on the active surface of the chip body 731. FIGS. 7 to 9 illustrate one chip conductive pad 732, but example embodiments are not limited thereto. Two chip conductive pads 732 may be provided. Some of the chip conductive pads 732 may serve as an input terminal, and other chip conductive pads 732 may serve as an output terminal. For example, the chip conductive pad 732 may include a conductive material that includes, for example, copper (Cu), gold (Au), silver (Ag), nickel (Ni), tungsten (W), aluminum (Al), or a combination thereof.

According to an example embodiment, the chip region CA of the glass substrate 110 may include a stepped region 110a_P. The stepped region 110a_P may be located in the outermost portion of the first surface 110a of the glass substrate 110 in the first horizontal direction (X direction). The stepped region 110a_P may have a small height in the vertical direction (Z direction) compared to the remaining regions excluding the chip region CA. The stepped region 110a_P may also exist in the second surface 110b of the glass substrate 110. A hole H extending in the vertical direction (Z direction) may be formed in the stepped region 110a_P. The hole H may extend from the first surface 110a to the second surface 110b of the glass substrate 110 in the stepped region 110a_P. The hole H may be provided in plurality, and the plurality of holes H may be spaced apart from each other in the second horizontal direction (Y direction).

The display device 30 may include a plurality of conductive connectors 720 arranged in the stepped region 110a_P and a first conductive wire 610a and a second conductive wire 610b electrically connected to the conductive connectors 720. Each of the conductive connectors 720 may include a vertical upper pad 721, a vertical lower pad 722, and a conductive pillar 723. The conductive pillar 723 may fill the hole H formed in the stepped region 110a_P. The length of the conductive pillar 723 in the vertical direction (Z direction) may be equal to the length of the glass substrate 110 in the stepped region 110a_P in the vertical direction (Z direction).

The vertical upper pad 721 may be disposed on the upper surface of the conductive pillar 723, and the vertical lower pad 722 may be disposed on the lower surface of the conductive pillar 723. The vertical upper pad 721 may be connected to one end of the first conductive wire 610a. Accordingly, the vertical upper pad 721 may be electrically connected to the chip conductive pad 732 of the semiconductor chip 730 via the first conductive wire 610a.

According to the present example embodiment, the semiconductor devices 740a, 740b, and 740c (or referred to as the first to third semiconductor devices 740a, 740b, and 740c) may be disposed on the second surface 110b of the glass substrate 110. The first to third semiconductor devices 740a, 740b, and 740c may be bonded to the second surface 110b of the glass substrate 110 by a plurality of adhesive layers 742a, 742b, and 742c (or referred to as first to third adhesive layers 742a, 742b, and 742c), respectively. The first to third semiconductor devices 740a, 740b, and 740c shown in FIGS. 7 to 9 are substantially the same as or similar to the first to third semiconductor devices 140a, 140b, and 140c shown in FIGS. 1 to 3, except that the first to third semiconductor devices 740a, 740b, and 740c are bonded, in a face-up state, to the glass substrate 110.

The first semiconductor device 740a may include a first substrate 741a, a first adhesive layer 742a, and a first conductive pad 743a, and the second semiconductor device 740b may include a second substrate 741b, a second adhesive layer 742b, and a second conductive pad 743b. Also, the third semiconductor device 740c may include a third substrate 741c, a third adhesive layer 742c, and a third conductive pad 743c. The first to third substrates 741a, 741b, and 741c shown in FIGS. 7 to 9 are substantially the same as the first to third substrates 141a, 141b, and 141c shown in FIGS. 1 to 3, except that the first to third substrates 741a, 741b, and 741c are in a face-up state in which the first to third conductive pads 743a, 743b, and 743c are disposed on the upper surfaces (e.g., a surface facing downward in FIG. 8) thereof. The upper surfaces of the first to third semiconductor devices 740a, 740b, and 740c may include active surfaces, and the first to third adhesive layers 742a, 742b, and 742c may be attached along the inactive surfaces of the first to third substrates 741a, 741b, and 741c, respectively.

The first to third conductive pads 743a, 743b, and 743c may be disposed on the active surfaces of the first to third substrates 741a, 741b, and 741c, respectively. FIGS. 7 to 9 illustrate one first conductive pad 743a, one second conductive pad 743b, and one third conductive pad 743c, but example embodiments are not limited thereto. Two first conductive pads 743a, two second conductive pads 743b, and two third conductive pads 743c may be provided. Some of the first to third conductive pads 743a, 743b, and 743c may serve as an input terminal, and other first to third conductive pads 743a, 743b, and 743c may serve as an output terminal. For example, each of the first to third conductive pads 743a, 743b, and 743c may include a conductive material that includes copper (Cu), gold (Au), silver (Ag), nickel (Ni), tungsten (W), aluminum (Al), or a combination thereof.

The vertical lower pad 722 may be connected to one end of the second conductive wire 610b. Accordingly, the vertical lower pad 722 may be electrically connected to the first conductive pad 743a of the first semiconductor device 740a via the second conductive wire 610b. FIG. 8 shows that only the first semiconductor device 740a is electrically connected to the conductive connector 720 via the second conductive wire 610b, but example embodiments are not necessarily limited thereto. The second semiconductor device 740b and the third semiconductor device 740c may also be electrically connected to the conductive connector 720 via a conductive wire.

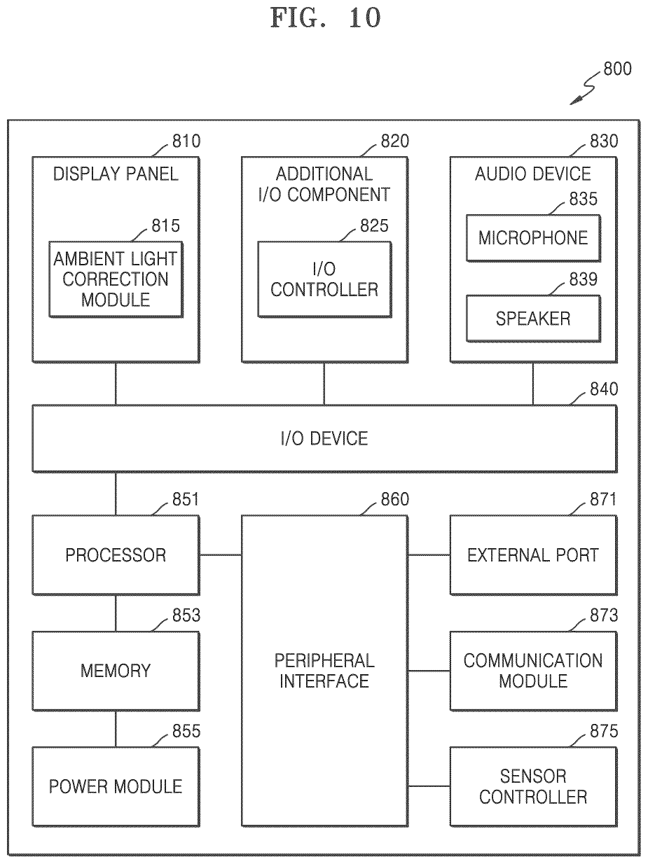

FIG. 10 is a system diagram including a display device according to an example embodiment.

FIG. 10 shows a diagram of a display system 800 according to an example embodiment, and the display system 800 includes a display panel 810 described below. The display system 800 may include a processor 851 and memory 853 for managing the system and executing instructions. The memory 853 may include non-volatile memory, such as flash memory. In addition, the memory 853 may include volatile memory, such as static or dynamic RAM. The memory 853 may further include a part dedicated to read only memory (ROM) to store firmware and configuration utilities.

In the present example embodiment, the processor 851 may control a microchip that outputs light to light emitting diode (LED) devices in which the light output is adjusted based on optical sensor data from a sensor controller 875 and may manage ambient light correction of the display panel 810. In some example embodiments, an ambient light correction module 815 may be located in each of microchips within the display panel 810.

The display system 800 also may include a power module 855 (e.g., a flexible battery, a wired or wireless charging circuit, etc.), a peripheral interface 860, and one or more external ports 871 (e.g. a universal serial bus (USB), a high-definition multimedia interface (HDMI), a display port, and/or the like). For example, a communication module 873 may include one or more transceivers functioning according to IEEE standards, 3GPP standards, or other communication standards and configured to receive and transmit data via the one or more external ports 871.

The communication module 873 may include one or more wireless wide area network (WWAN) transceivers configured to communicate with a wide area network that includes one or more cellular towers. Also, base stations may be provided to communicate the display system 800 with additional devices or components. Furthermore, the communication module 873 may include one or more wireless local area network (WLAN) and/or wireless personal area network (WPAN) transceivers configured to connect the display system 800 to a local area network and/or a personal area network, such as a Bluetooth network.

The display system 800 may further include the sensor controller 875 for managing inputs from one or more sensors, for example, proximity sensors, ambient light sensors, or infrared transceivers. In an example embodiment, an array of microchips on the display panel includes an array of optical sensors in communication with the sensor controller 875. Each of microchips may include an optical sensor, or only a portion of the array of microchips may include optical sensors. For example, the array of optical sensors may be uniformly distributed within the array of microchips.

The system may include an audio device 830 that includes one or more speakers 839 for outputting audio signals and one or more microphones 835 for receiving audio signals. In some example embodiments, the speakers 839 and the microphones 835 may include piezoelectric components. The display system 800 may include some of an I/O controller 825, a display panel 810, and additional I/O components 820 (e.g., keys, buttons, lamps, LEDs, cursor control devices, haptic devices, etc.). The display panel 810 and the additional I/O components 820 may be considered to form parts of a user interface (e.g., parts of display system 800 associated with presenting information to and/or receiving inputs from a user).

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A display device comprising:
a glass substrate having a first surface including a chip region and a display region, a second surface opposite to the first surface, and a third surface extending from the first surface and the second surface and being perpendicular to the first surface;
a display panel in the display region on the first surface of the glass substrate;
a semiconductor chip in the chip region on the first surface of the glass substrate;
a wiring structure surrounding the chip region on the first surface of the glass substrate and the second surface and the third surface of the glass substrate; and
a plurality of semiconductor devices below the second surface of the glass substrate.

2. The display device of claim 1, wherein the wiring structure is bent at a corner of the glass substrate in a cross-section and extends along a direction perpendicular to the first surface of the glass substrate.

3. The display device of claim 1, wherein the wiring structure comprises:
a first redistribution structure in contact with the first surface of the glass substrate;
a second redistribution structure in contact with the second surface of the glass substrate; and
a third redistribution structure in contact with the third surface of the glass substrate,
wherein the semiconductor chip is on the first redistribution structure and electrically connected to the first redistribution structure, and
the plurality of semiconductor devices are on the second redistribution structure and electrically connected to the second redistribution structure.

4. The display device of claim 3, wherein the wiring structure further comprises:
a first conductive layer between the first redistribution structure and the third redistribution structure and configured to bond the first redistribution structure to the third redistribution structure; and
a second conductive layer between the second redistribution structure and the third redistribution structure and configured to bond the second redistribution structure to the third redistribution structure,
wherein a width of the first conductive layer is equal to a width of the first redistribution structure, and a width of the second conductive layer is equal to a width of the second redistribution structure.

5. The display device of claim 4, wherein
the first conductive layer has a first side surface in contact with the glass substrate and a second side surface opposite to the first side surface and coplanar with an upper surface of the first redistribution structure, and
the second conductive layer has a third side surface in contact with the glass substrate and a fourth side surface opposite to the third side surface and coplanar with a lower surface of the second redistribution structure.

6. The display device of claim 4, wherein
the first redistribution structure comprises a first insulating layer and a first conductive pattern buried in the first insulating layer and extending in a lateral direction,
the second redistribution structure comprises a second insulating layer and a second conductive pattern buried in the second insulating layer and extending in the lateral direction, and
the third redistribution structure comprises a third insulating layer and a third conductive pattern buried in the third insulating layer and extending in a vertical direction perpendicular to the first surface of the glass substrate,
wherein the first conductive layer is in contact with the first conductive pattern and the third conductive pattern, and the second conductive layer is in contact with the second conductive pattern and the third conductive pattern.

7. The display device of claim 1, further comprising:
a molding layer sealing the plurality of semiconductor devices,
wherein the molding layer is in contact with the wiring structure.

8. The display device of claim 1, wherein the chip region is in an outer circumferential portion on the first surface of the glass substrate in a plan view.

9. The display device of claim 1, wherein a height of the glass substrate is in a range from about 0.1 mm to about 3 mm.

10. The display device of claim 1, further comprising:
a battery disposed below the second surface of the glass substrate.

11. The display device of claim 1, wherein the wiring structure comprises a plurality of conductive lines extending from the chip region on the first surface of the glass substrate to the second surface of the glass substrate via the third surface of the glass substrate.

12. The display device of claim 11, wherein the plurality of conductive lines are in contact with the first surface, the second surface, and the third surface of the glass substrate.

13. A display device comprising:
a glass substrate having a first surface including a chip region and a display region, a second surface opposite to the first surface, and a third surface extending from the first surface and the second surface and being perpendicular to the first surface;
a display panel in the display region on the first surface of the glass substrate;
a wiring structure extending from the chip region on the first surface of the glass substrate to the second surface of the glass substrate via the third surface of the glass substrate;
a semiconductor chip in the chip region on the first surface of the glass substrate and aligned with the display panel in a lateral direction;
a plurality of semiconductor devices below the second surface of the glass substrate; and
a molding layer being in contact with the second surface of the glass substrate and sealing the plurality of semiconductor devices.

14. The display device of claim 13, wherein the semiconductor chip does not overlap the display panel in a vertical direction perpendicular to the first surface of the glass substrate.

15. The display device of claim 13, wherein
the wiring structure comprises a plurality of wiring patterns integrally extending from the chip region on the first surface of the glass substrate to the second surface of the glass substrate via the third surface of the glass substrate, and
the plurality of wiring patterns are electrically connected to the semiconductor chip and the plurality of semiconductor devices.

16. The display device of claim 13, wherein the wiring structure is between the molding layer and the second surface of the glass substrate.

17. The display device of claim 13, wherein the display region on the first surface of the glass substrate is greater than the chip region on the first surface of the glass substrate.

18. The display device of claim 13, further comprising:
a battery below the second surface of the glass substrate.

19. A display device comprising:
a glass substrate having a first surface including a chip region and a display region, a second surface opposite to the first surface, and a third surface extending from the first surface and the second surface and being perpendicular to the first surface;
a display panel in the display region on the first surface of the glass substrate;
a wiring structure comprising a first redistribution structure in contact with the first surface of the glass substrate, a second redistribution structure in contact with the second surface of the glass substrate, and a third redistribution structure in contact with the third surface of the glass substrate;
a semiconductor chip in the chip region on the first surface of the glass substrate and aligned with the display panel in a lateral direction;
a plurality of semiconductor devices below the second surface of the glass substrate; and
a molding layer in contact with the second surface of the glass substrate and sealing the plurality of semiconductor devices,
wherein the semiconductor chip is on the first redistribution structure and electrically connected to the first redistribution structure, and the second redistribution structure is electrically connected to the plurality of semiconductor devices.

20. The display device of claim 19, wherein the wiring structure further comprises:
a first conductive layer between the first redistribution structure and the third redistribution structure and configured to bond the first redistribution structure to the third redistribution structure; and
a second conductive layer between the second redistribution structure and the third redistribution structure and configured to bond the second redistribution structure to the third redistribution structure,
wherein a width of the first conductive layer is equal to a width of the first redistribution structure, and a width of the second conductive layer is equal to a width of the second redistribution structure.
